(19) United States
(12) Patent Application Publication
(10) Pub. No.: US 2009/0200063 A1
(43) Pub. Date: Aug. 13, 2009

(54) EMBEDDED SPARK GAP

(75) Inventor: Idris Omerovic, Malmo (SE)

Correspondence Address: HARRITY & HARRITY, LLP, 11350 RANDOM HILLS ROAD, SUITE 600, FAIRFAX, VA, 22030, US

(73) Assignee: SONY ERICSSON MOBILE COMMUNICATIONS AB, Lund (SE)

(21) Appl. No.: 12/028,164

(22) Filed: Feb. 8, 2008

(51) Int. Cl. H05K 1/02; H05K 7/06

(52) U.S. Cl. 174/250; 361/748

(57) ABSTRACT

A multilayer printed circuit board may include a first layer, a second layer, and a third layer, the second layer being between the first layer and the second layer. The second layer may include a spark gap.

### BACKGROUND

Printed circuit boards (PCBs) facilitate the construction of electronic circuits by providing a structure upon which components may be mounted. The components may be interconnected using conductive lines or traces bonded to a substrate or a board to form circuit paths. There are various types of PCBs, such as single-sided, double-sided, multilayer, flexible, rigid, etc.

To prevent damage to components on PCBs caused by electrostatic discharge (ESD), spark gaps may be employed. For example, a spark gap may be formed on a top surface of a PCB to direct or dissipate energy toward a ground. However, the spark gap may become adulterated based on an exposure to moisture or other environmental pollution. In this regard, the performance of the spark gap and/or the PCB may be less than optimal.

### SUMMARY

According to one aspect, a multilayer printed circuit board may include a first layer, a second layer, and a third layer. The second layer may be between the first layer and the third layer. The second layer may include a spark gap.

Additionally, the second layer may include a ground trace, and the spark gap may be proximate to the ground trace.

Additionally, the second layer may include a signal trace, and the spark gap may be proximate to the signal trace.

Additionally, the spark gap may include air.

Additionally, the spark gap may include a gas.

Additionally, the spark gap may include a liquid.

Additionally, the first layer may include a board.

Additionally, the third layer may include a board.

According to another aspect, a device may include a printed circuit board. The printed circuit board may include a first layer having electronic components thereon, a second layer including a spark gap, and a third layer. The second layer may be between the first layer and the third layer.

Additionally, the device may include a portable device.

Additionally, the portable device may include at least one of a telephone, a computer, a music player, or a video player.

Additionally, the spark gap may be between conductive materials of the second layer.

Additionally, the conductive materials may include a ground trace or a signal trace.

Additionally, the printed circuit board may include a fourth layer, and the third layer may be between the second layer and the fourth layer. The third layer may include a spark gap.

According to yet another aspect, a printed circuit board may include an embedded ground, an embedded conductive element, and a spark gap between the embedded ground and the embedded conductive element to provide protection from electrostatic discharge.

Additionally, the spark gap may include a dielectric material.

Additionally, the spark gap may include a material configured to conduct when exposed to a first voltage level.

Additionally, the embedded conductive element may include a signal trace.

Additionally, the spark gap may include air or neon.

Additionally, the spark gap may include a first surface adjacent a first nonconductive element and a second surface adjacent a second nonconductive element.

Additionally, the first and the second nonconductive elements may include boards.

### BRIEF DESCRIPTION OF THE DRAWINGS

The accompanying drawings, which are incorporated in and constitute a part of this specification, illustrate exemplary embodiments described herein and, together with the description, explain these exemplary embodiments. In the drawings:

FIG. 1. is a diagram illustrating concepts described herein;

FIG. 2 is a diagram illustrating an exemplary multilayer printed circuit board including an exemplary embedded spark gap; and

FIGS. 3-6 are diagrams illustrating exemplary topologies for exemplary embedded spark gaps.

### DETAILED DESCRIPTION

The following detailed description refers to the accompanying drawings. The same reference numbers in different drawings may identify the same or similar elements. Also, the following description does not limit the invention.

The term “PCB,” as used herein, is intended to be broadly interpreted to include any platform to support and/or electrically connect electronic components (e.g., digital components, analog components, or a combination thereof). The PCB may include a non-conducting substrate or board (e.g., Flame Retardant (FR) family (FR-4, etc.), Composite Epoxy Material (CEM) family (CEM-3, etc.), polyimide, Teflon, ceramic, polyester, Kapton, Pyralux, etc). The PCB may include a conductive layer (e.g., metallization) on its top and/or bottom. The PCB may be rigid, flexible, or a combination thereof (e.g., rigid-flexible).

The term “spark gap,” as used herein, is intended to be broadly interpreted to include a gap to provide ESD protection. As will be described below, the spark gap may have various topologies and may include various kinds of matter (e.g., a gas, a liquid, a material, air, etc.).

### Overview

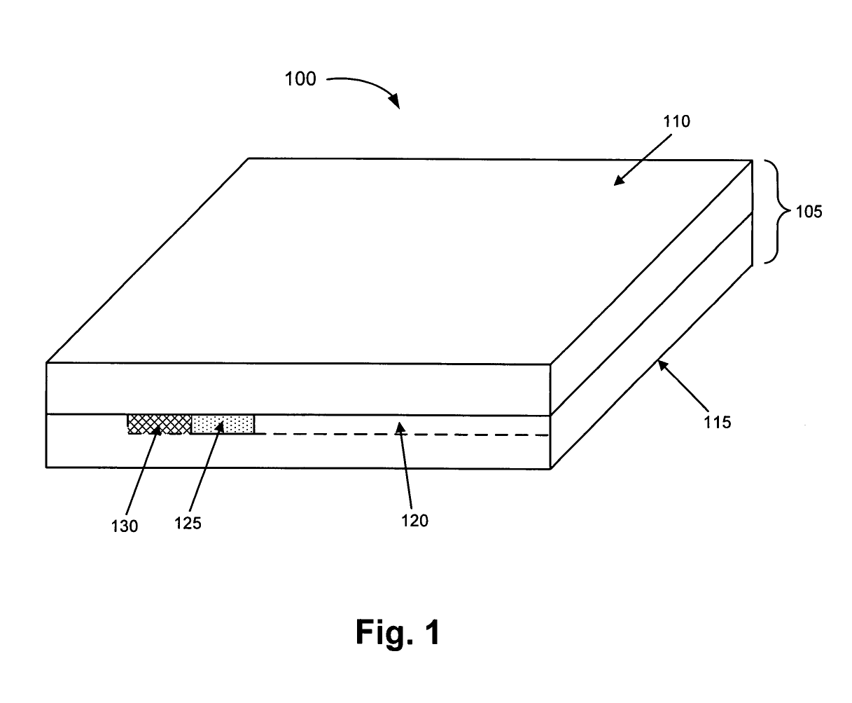

FIG. 1 is a diagram illustrating an exemplary multilayer PCB 100. PCB 100 may include boards (or substrates) 105 having a top surface 110 and a bottom surface 115. Boards 105 may include, among other things, a ground 120, a spark gap 125, and a signal trace 130. However, unlike other spark gaps that reside on or are proximate to a top surface or a bottom surface of a PCB, spark gap 125 may be embedded in PCB 100.

As a result of the foregoing, an embedded spark gap may not degrade due to exposure to environmental conditions. Further, an embedded spark gap may save space on, for example, a top surface and/or a bottom surface of a PCB, and allow another component to occupy that space.

It will be appreciated that the concepts described herein have been broadly described in connection with FIG. 1. Accordingly, variations to the concepts in connection with FIG. 1 exist, and will be described further in the detailed description provided below.

### Exemplary Multilayer PCB

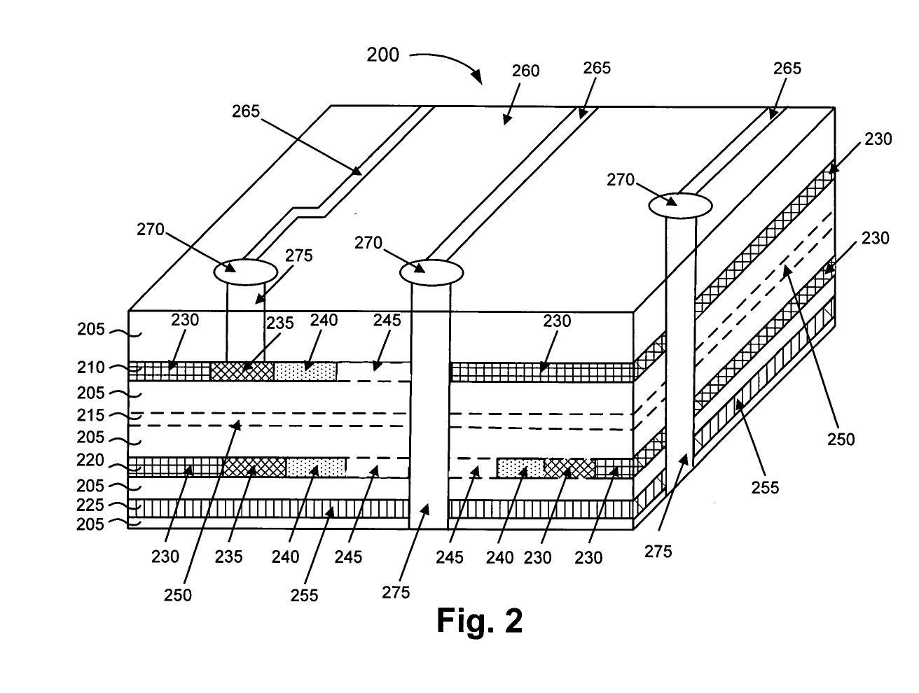

An exemplary multilayer PCB having an embedded spark gap will be described and illustrated below with respect to FIG. 2. It will be appreciated that the arrangement, topology, and/or components described with respect to the multilayer PCB may be different in other implementations. Additionally, or alternatively, multilayer PCB may include fewer or additional layers and/or components.

FIG. 2 is a diagram illustrating an exemplary multilayer PCB 200. As illustrated, PCB 200 may include boards or substrates 205 (hereinafter referred to simply as boards 205), and intermediary layers 210, 215, 220, and 225.

Boards 205 may include a non-conducting substance (e.g., an epoxy-fiberglass composite material, as previously described). Intermediary layers 210 and 220 may include an adhesive layer 230, a conductive layer 235, an embedded spark gap 240, and a ground layer 245.

Adhesive layer 230 may include a non-conductive material (e.g., an epoxy resin). Conductive layer 235 may include a conductive material (e.g., cooper, silver, gold, aluminum, nickel and/or tin).

Embedded spark gap 240 may include any form of matter or substance, such as air, a gas (e.g., neon), a liquid (e.g., argon or a mineral oil), a solid (e.g., a dielectric material), or a vacuum that can be used as an ESD mechanism. Ground layer 245 may include a conductive layer (e.g., cooper, silver, gold, aluminum, nickel and/or tin) that is coupled to a ground or a ground pin.

Intermediary layer 215 may include a ground plane 250. Ground plane 250 may include a conductive plane (e.g., cooper, silver, gold, aluminum, nickel and/or tin). Intermediary layer 225 may include a power plane 255. Power plane 255 may include a conductive plane (e.g., cooper, silver, gold, aluminum, nickel and/or tin). Ground plane 250 and power plane 255 may provide the voltages delivered to various regions of PCB 200.

Top surface 260 of PCB 200 may include signal traces 265 and pads 270. Signal traces 265 may include a conductive metal (e.g., cooper, silver, gold, aluminum, nickel and/or tin) that interconnects various components (not illustrated) on PCB 200. Signal traces 265 may form patterns having various orientations and shapes on top surface 260. Pads 270 may include a conductive metal (e.g., cooper, silver, gold, aluminum, nickel and/or tin). Although not illustrated, PCB 200 may include additional components, such as electronic components mounted on a top surface 260 of PCB 200 to provide a printed circuit assembly (PCA) or printed circuit board assembly (PCBA).

PCB 200 may also include vias 275. Vias 275 may include a conductive material (e.g., cooper, silver, gold, aluminum, nickel and/or tin) that interconnects components located on different layers or levels of PCB 200. In some instances, vias 275 may be plated (i.e., a plated through-hole).

As illustrated in FIG. 2, in one implementation, embedded spark gap 240 may provide ESD protection by transporting ESD that originated from, for example, signal trace 235, to ground 245. In some instances, depending on the specifications or particular components of the PCB, a precise spark break-in voltage may be desired. In such instances, embedded spark gap 240 may include a material that remains non-conductive until a certain level voltage (e.g., a voltage associated with ESD) is applied, in which embedded spark gap 240 may break and may become conductive to transport ESD to ground 245.

Spark gap 240 distances may vary depending on the material employed. For example, if neon is utilized, spark gap 240 may have a distance range between 2 mm to 2 cm. However, depending on the amount of neon utilized and/or the break-in voltage desired, the distance may be below 2 mm or above 2 cm. In another example, if air is utilized, spark gap 240 may have a distance range between 5 mm to 1 cm. However, depending on the amount of air utilized and/or the break-in voltage desired, the distance may be below 5 mm or above 1 cm.

It will be appreciated that multilayer PCB 200 may be incorporated in numerous devices. The term “device,” is intended to be broadly interpreted to include any electronic device that includes a PCB. Given the expansive nature of electronic devices that include PCBs, it will be appreciated that the concepts described herein may be employed in any number of devices, such as portable devices (e.g., a wireless telephone, a personal digital assistant (PDA), a laptop computer, a printer), stationary devices (e.g., a desktop computer, a television, stereo systems), transportation vehicles (e.g., a car or an airplane), etc.

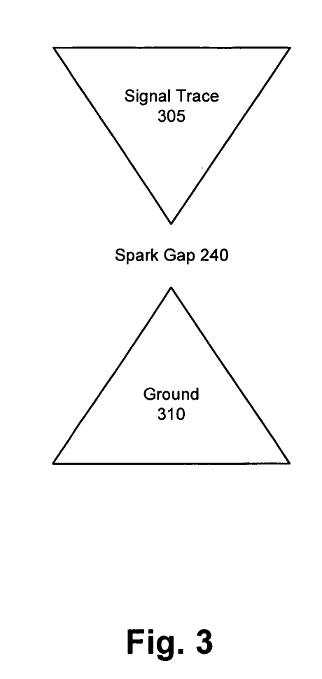

FIGS. 3-6 are diagrams illustrating exemplary topologies of embedded spark gap 240. In each of FIGS. 3-6, a signal trace, a ground, and embedded spark gap 240 are schematically illustrated. It will be appreciated that embedded spark gap 240 may reside in any region between the signal trace and the ground. Further, it will be appreciated that parameters such as shape, substance, distance from signal trace(s) to ground, etc., may be based on the particular components associated with PCB 200.

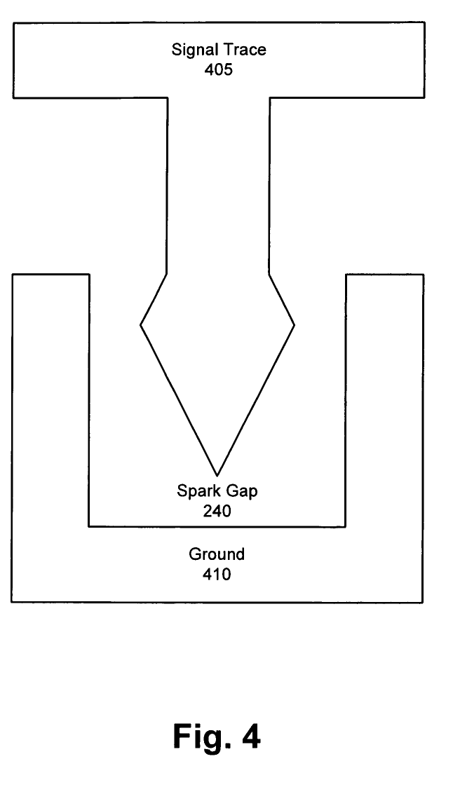

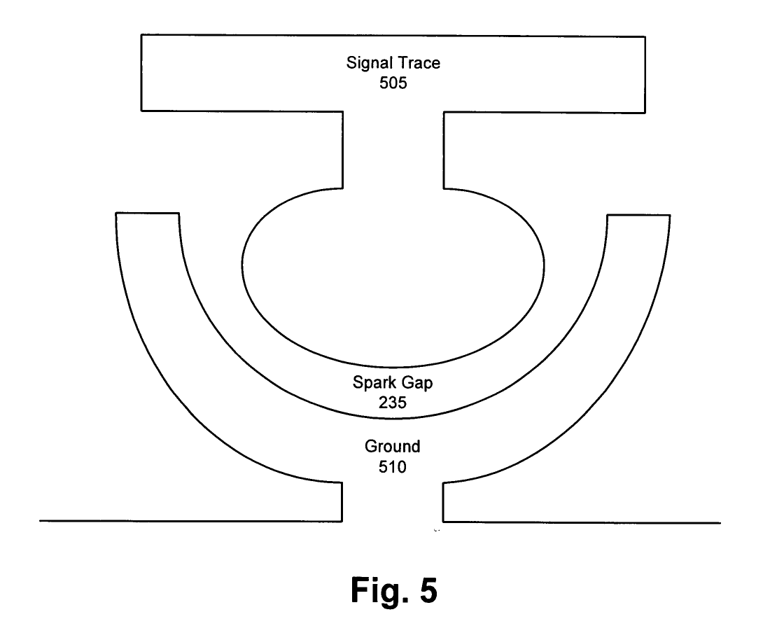

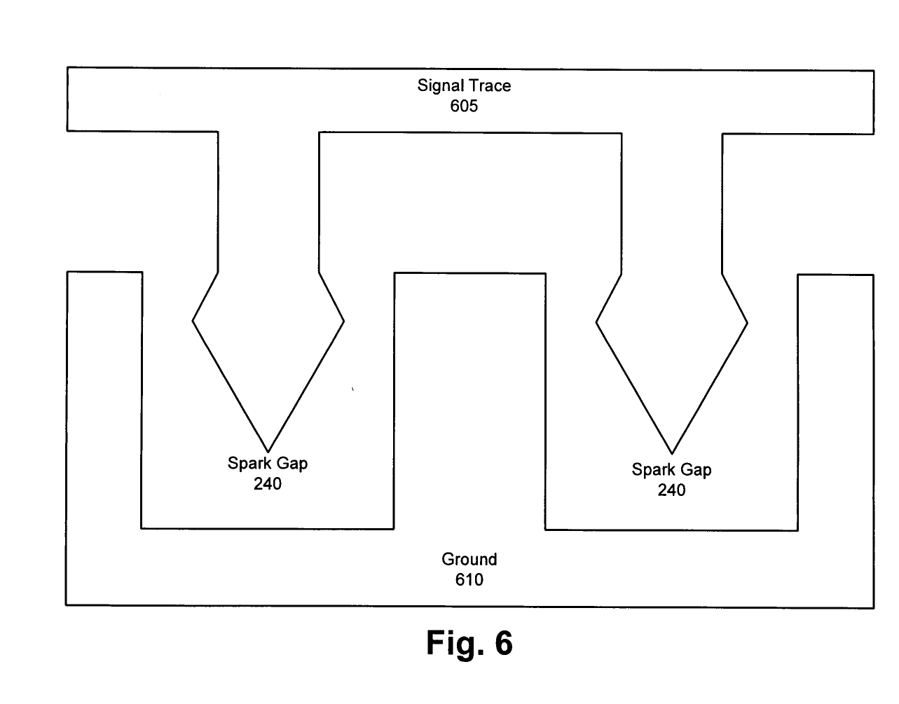

FIG. 3 illustrates a top view of triangular geometries for signal trace 305 and ground 310. As illustrated, embedded spark gap 240 may reside in a region between signal trace 305 and ground 310 to provide a controlled area for discharge of ESD. FIG. 4 illustrates a top view of a signal trace 405 having a “T” shaped configuration and ground 410 having a “U” shaped configuration. Embedded spark gap 240 may be arranged between signal trace 405 and ground 410. FIG. 5 illustrates a top view of another exemplary arrangement where signal trace 505 and ground 510 each includes an arc or curved shape. Embedded spark gap 240 may be situated between signal trace 505 and ground 510 in regions where ESD may occur. FIG. 6 is a diagram illustrating a top view of serial and/or multiple embedded spark gaps 240 in relation to signal trace 605 and ground 610 to provide ESD protection.

The arrangements illustrated and described herein are exemplary and are not intended to be exhaustive. That is, a ground plane, a ground trace, and/or a signal trace may have any number of shapes on a given layer of the PCB. Additionally, although FIGS. 3-6 illustrate embedded spark gap 240 between a signal trace and a ground, in other implementations, embedded spark gap 240 may be between conductive elements not corresponding to a signal trace and/or a ground. For example, the conductive element may correspond to a pad or some other component. In each case, a spark gap may be provided on a surface of PCB that is embedded within the PCB (i.e., a surface that is not exposed to external environmental conditions).

### CONCLUSION

The foregoing description of implementations provides illustration, but is not intended to be exhaustive or to limit the implementations to the precise form disclosed. Modifications and variations are possible in light of the above teachings or may be acquired from practice of the teachings. For example, a via may be connected to a spark gap of one layer to provide ESD protection to another layer of the PCB.

It should be emphasized that the term “comprises” or “comprising” when used in the specification is taken to specify the presence of stated features, integers, steps, or components but does not preclude the presence or addition of one or more other features, integers, steps, components, or groups thereof.

Even though particular combinations of features are recited in the claims and/or disclosed in the specification, these combinations are not intended to limit the invention. In fact, many of these features may be combined in ways not specifically recited in the claims and/or disclosed in the specification.

No element, act, or instruction used in the present application should be construed as critical or essential to the implementations described herein unless explicitly described as such. The term “may” is used throughout this application and is intended to be interpreted, for example, as “having the potential to,” “being configured to,” or “being able to,” and not in a mandatory sense (e.g., as “must”).

Also, as used herein, the article “a” and “an” are intended to include one or more items. Where only one item is intended, the term “one” or similar language is used. Further, the phrase “based on” is intended to mean “based, at least in part, on” unless explicitly stated otherwise. As used herein, the term “and/or” includes any and all combinations of one or more of the associated list items.

What is claimed is:

1. A multilayer printed circuit board comprising:
a first layer, a second layer, and a third layer, the second layer being between the first layer and the third layer; and
the second layer includes a spark gap.

2. The printed circuit board of claim 1, where the second layer includes a ground trace, and the spark gap is proximate to the ground trace.

3. The printed circuit board of claim 2, where the second layer includes a signal trace, and the spark gap is proximate to the signal trace.

4. The printed circuit board of claim 1, where the spark gap includes air.

5. The printed circuit board of claim 1, where the spark gap includes a gas.

6. The printed circuit board of claim 1, where the spark gap includes a liquid.

7. The printed circuit board of claim 1, where the first layer includes a board.

8. The printed circuit board of claim 7, where the third layer includes a board.

9. A device comprising:
a printed circuit board, the printed circuit board comprising:
a first layer having electronic components thereon;
a second layer including a spark gap; and
a third layer, where the second layer is between the first layer and the third layer.

10. The device of claim 9, where the device is a portable device.

11. The device of claim 10, where the portable device is at least one of a telephone, a computer, a music player, or a video player.

12. The device of claim 9, where the spark gap is between conductive materials of the second layer.

13. The device of claim 12, where the conductive materials include a ground trace or a signal trace.

14. The device of claim of claim 9, where the printed circuit board further comprises:
a fourth layer, where the third layer is between the second layer and the fourth layer; and
the third layer includes a spark gap.

15. A printed circuit board comprising:
an embedded ground;
an embedded conductive element; and
a spark gap between the embedded ground and the embedded conductive element to provide protection from electrostatic discharge.

16. The printed circuit board of claim 15, where the spark gap comprises:
a dielectric material.

17. The printed circuit board of claim 15, where the spark gap includes a material configured to conduct when exposed to a first voltage level.

18. The printed circuit board of claim 15, where the embedded conductive element includes a signal trace.

19. The printed circuit board of claim 15, where the spark gap comprises:
air or neon.

20. The printed circuit board of claim 15, where the spark gap has a first surface adjacent a first nonconductive element and a second surface adjacent a second nonconductive element.

21. The printed circuit board of claim 20, where the first and the second nonconductive elements are boards.
